(19) United States
(12) Patent Application Publication
(10) Pub. No.: US 2005/0041409 A1
(43) Pub. Date: Feb. 24, 2005

(54) EMI protective cover

(75) Inventor: Chia-Wei Liao, Taichung City (TW)

Correspondence Address: BACON & THOMAS, PLLC, 625 SLATERS LANE, FOURTH FLOOR, ALEXANDRIA, VA, 22314, US

(73) Assignee: SPEED TECH CORP., Taoyuan Hsien (TW)

(21) Appl. No.: 10/642,696

(22) Filed: Aug. 19, 2003

(51) Int. Cl. H05K 9/00

(52) U.S. Cl. 361/816

(57) ABSTRACT

An EMI protective cover is constructed to include a bottom cover shell for covering on the circuit board over electronic components, the bottom cover shell having stub pins around the four sides and an inspection hole in the top wall, and a top cover shell detachably covered on the bottom cover shell, the top cover shell having springy mounting lugs and smoothly arched springy retaining lugs arranged around the four sides and respectively pressed on the peripheral walls of the bottom cover shell, the springy mounting lugs each having a pin hole respectively forced into engagement with the stub pins of the bottom cover shell. The electronic components are accessible through the inspection hole after removal of the top cover shell from the bottom cover shell.

### BACKGROUND OF THE INVENTION

1. Field of the Invention

The present invention relates to an EMI protective cover for installation in a circuit board to protect electronic components against electromagnetic interference and, more particularly to such an EMI protective cover, which is comprised of a bottom cover shell with an inspection hole, and a top cover shell detachably fastened to the bottom cover shell.

2. Description of the Related Art

Following fast commercial and industrial progress, sophisticated electronic and communication products have been continuously developed. To fit market tendency, electronic and communication products are made lighter, thinner, shorter, and smaller. For example, pocket size cellular telephones and PDAs (personal digital assistants) are commercially available. These electronic components use thin IC chips. These IC chips must be well protected against EMI (electromagnetic interference) during their operation. FIGS. 9 and 10 show an EMI protective cover, entitled “Cellular Telephone EMI Shielding Device”. This structure of EMI protective cover is comprised of a cover shell A and a plurality of mounting bars B. The cover shell A is stamped from a metal sheet material, having two vertical mounting flanges A1 at two sides. Each vertical mounting flange A1 has a plurality of retaining holes A11. The mounting bars B has a plurality of hooks B1 for hooking in the retaining holes A11 of the cover shell A. This structure of EMI protective cover is still not satisfactory in function. When wishing the examine the electronic component C1 of the circuit board C, the inspector must bend the mounting flanges A1 outwards to disengage the retaining holes A11 from the hooks B1, for enabling the cover shell A to be removed from the circuit board C. Bending the mounting flanges A1 outwards from the mounting bars B may cause a permanent deformation of the cover shell A. Further, the strict precision requirement between the retaining holes A11 and the hooks B1 complicates the fabrication of the EMI protective cover.

Therefore, it is desirable to provide an EMI protective cover that eliminates the aforesaid drawbacks.

### SUMMARY OF THE INVENTION

The present invention has been accomplished under the circumstances in view. According to one aspect of the present invention, the EMI protective cover is comprised of a bottom cover shell for covering on the circuit board over electronic components, and a top cover shell detachably covered on the bottom cover shell. The bottom cover shell has stub pins around the four sides and an inspection hole in the top wall. The top cover shell has springy mounting lugs and smoothly arched springy retaining lugs arranged around the four sides and respectively pressed on the peripheral walls of the bottom cover shell. The springy mounting lugs each have a pin hole respectively forced into engagement with the stub pins of the bottom cover shell. According to another aspect of the present invention, the springy mounting lugs and smoothly arched springy retaining lugs can be symmetrically arranged at opposite sides, or alternatively arranged around the four sides. According to still another aspect of the present invention, the springy retaining lugs curve inwardly toward the inside of the top cover shell for securing the top cover shell to the peripheral walls of the bottom cover shell positively. According to still another object of the present invention, the round holes of the top cover shell and the through holes and inspection hole of the bottom cover shell are not vertically aligned and respectively blocked by the top or bottom cover shell, providing a satisfactory shielding effect. According to still another aspect of the present invention, when the EMI protective cover installed in the circuit board, the top cover shell and the bottom cover shell provide a satisfactory grounding effect. According to still another aspect of the present invention, the inspector can insert a lever or like tool into the round holes of the top cover shell and then force the lever against the top wall of the bottom cover shell to lift the top cover shell from the bottom cover shell for enabling the top cover shell to be quickly removed from the bottom cover shell during an inspection work.

### BRIEF DESCRIPTION OF THE DRAWINGS

FIG. 1 is an elevational view showing an EMI protective cover installed in a circuit board according to the present invention.

FIG. 2 is an exploded view of FIG. 1.

FIG. 3 is an exploded, oblique rear side view of the EMI protective cover according to the present invention.

FIG. 4 is a sectional view of a part of the present invention before connection of the top cover shell to the bottom cover shell.

FIG. 5 is a sectional view of a part of the present invention, showing the top cover shell fastened to the bottom cove shell.

FIG. 6 is a side view in section of the present invention, showing a lever inserted into one round hole of the top cover shell and pressed on the top wall of the bottom cover shell.

FIG. 7 is similar to FIG. 6 but showing the top cover shell lifted from the bottom cover shell.

FIG. 8 is similar to FIG. 8 but showing the top cover shell removed from the bottom cover shell.

FIG. 9 illustrates a prior art EMI protective cover installed in a circuit board according to the prior art.

FIG. 10 is an exploded view of FIG. 9.

### DETAILED DESCRIPTION OF THE PREFERRED EMBODIMENT

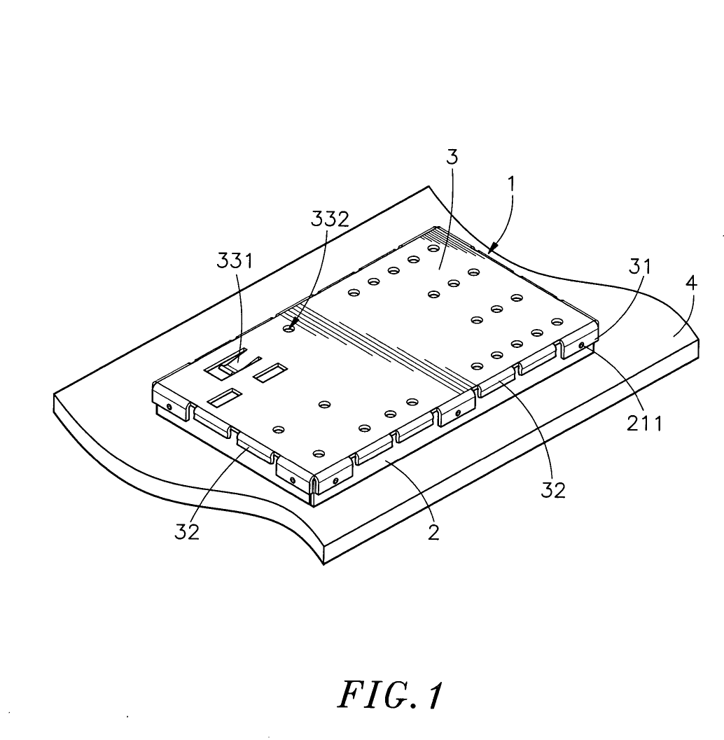

Referring to FIGS. 1˜3, an EMI protective cover 1 is shown comprised of a bottom cover shell 2 and a top cover shell 3.

The bottom cover shell 2 is a substantially [symbol] -shaped cover shell having a plurality of stub pins 211 perpendicularly outwardly extended from the vertical peripheral walls 21 around the four sides, and a plurality of through holes 222 and an inspection hole 221 through the top wall in communication with the inside space 22.

The top cover shell 3 covers the bottom cover shell 2, having a plurality of springy mounting lugs 31 and smoothly arched springy retaining lugs 32 perpendicularly downwardly extended around the four sides and respectively secured to the peripheral walls 21 of the bottom cover shell 2, the springy mounting lugs 31 each having a pin hole 311 respectively forced into engagement with the stub pins 211 of the bottom cover shell 2, a plurality of round holes 332 through the top wall in communication with the inside space 33, which receives the bottom cover shell 2, and a springy stop member 331 obliquely downwardly projecting into the inside space 33 and pressed on the top wall of the bottom cover shell 2.

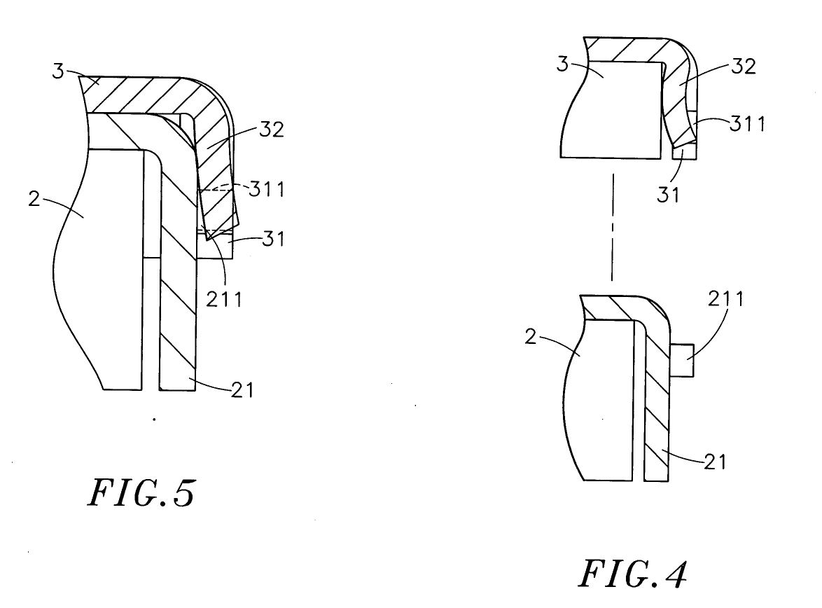

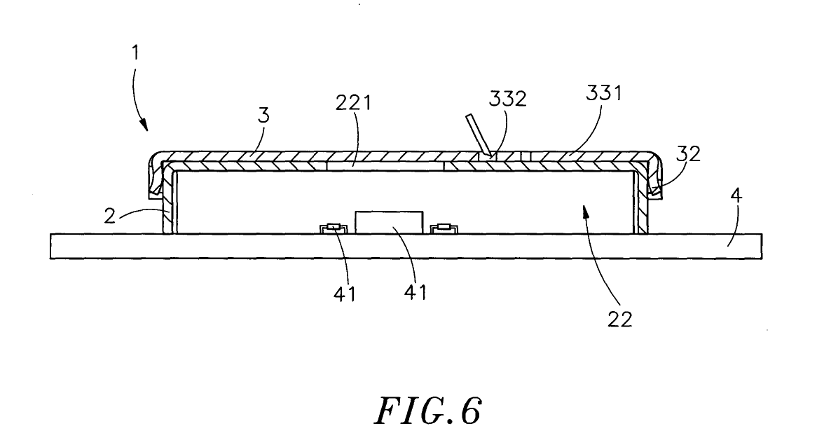

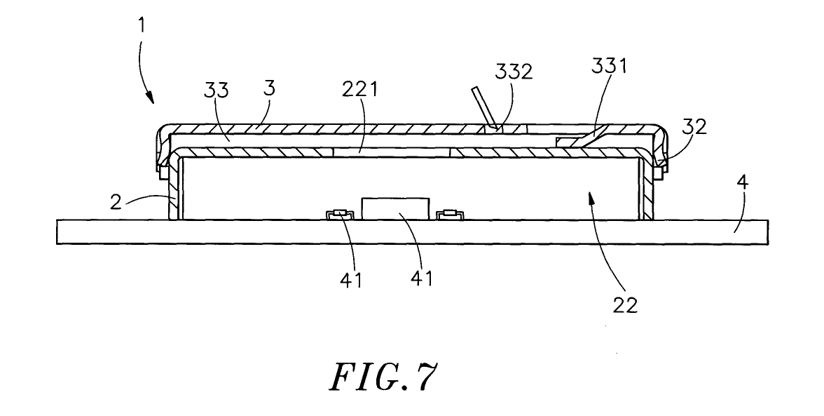

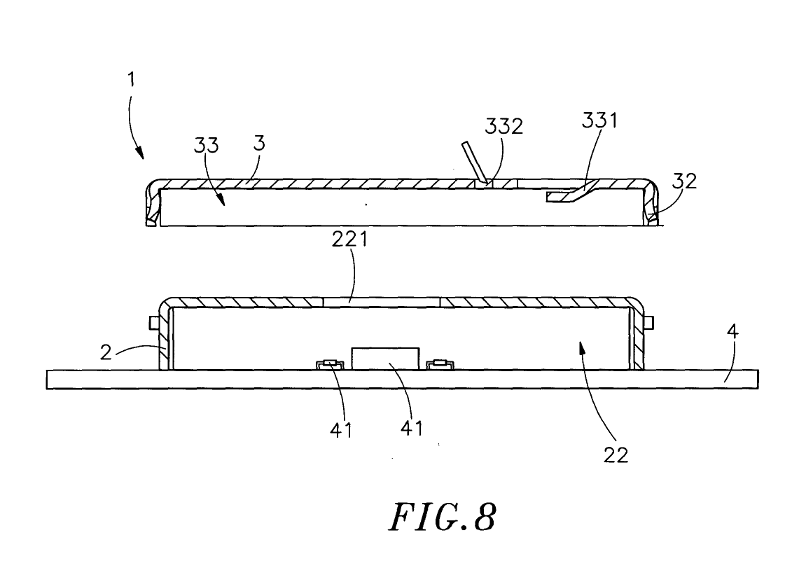

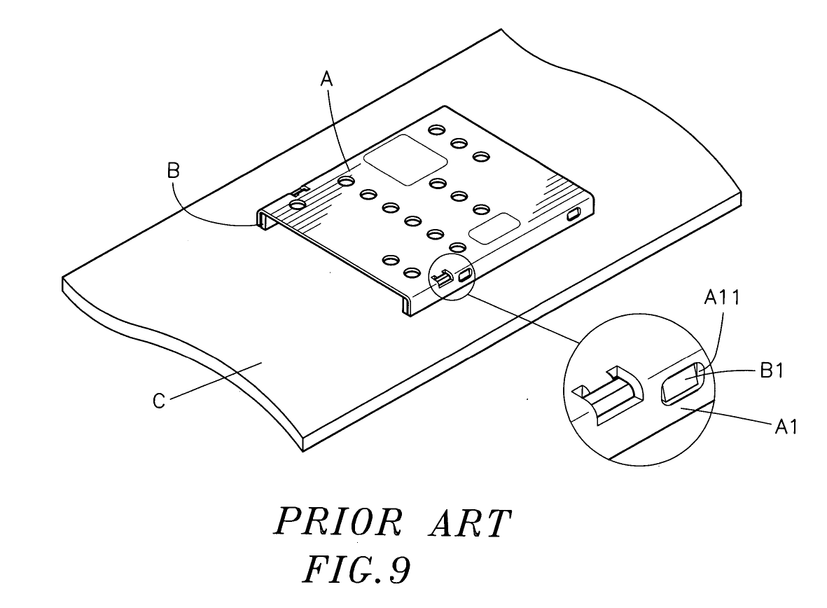

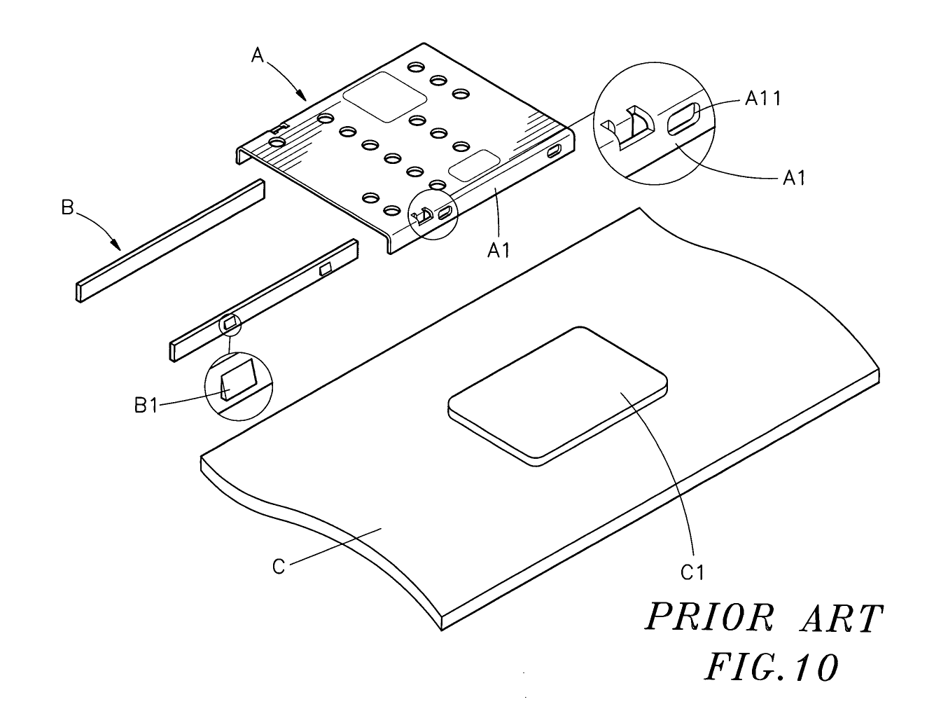

Referring to FIGS. 4˜8, when in use, the bottom cover shell 2 is covered on a circuit board 4 over an electronic components 41, and then the top cover shell 3 is covered on the bottom cover shell 2 to force the pin holes 311 of the springy mounting lugs 31 into engagement with the stub pins 211 (see FIGS. 4 and 5), keeping the springy retaining lugs 32 respectively pressed on the peripheral walls 21 of the bottom cover shell 2 and the springy stop member 331 pressed on the top wall of the bottom cover shell 2, and therefore the top cover shell 3 is firmly secured to the bottom cover shell 2 (see FIGS. 6˜8). When installed, the EMI protective cover 1 protects the electronic components 41 of the circuit board 4 against EMI (electromagnetic interference).

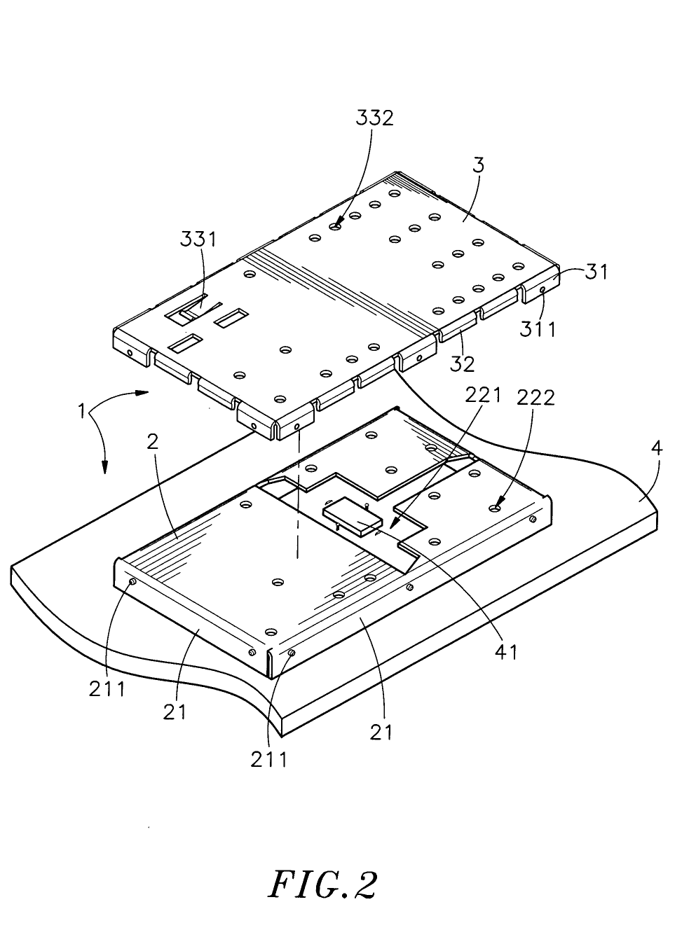

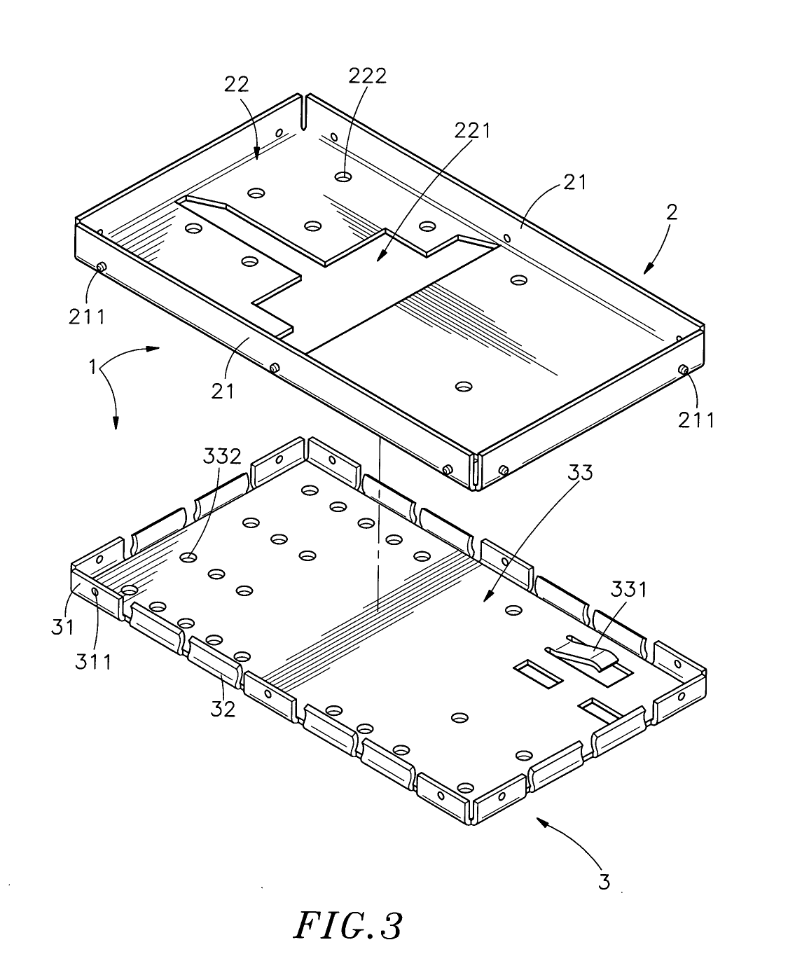

Referring to FIGS. 2 and 3 again, the springy mounting lugs 31 are arranged around the four corners of the top cover shell 3 and the middle of the two opposite long sides of the top cover shell 3 (the bottom cover shell 2 and the top cover shell 3 have a substantially rectangular profile), and the springy retaining lugs 32 are spaced between each two adjacent springy mounting lugs 31. The spring mounting lugs 31 and the springy retaining lugs 32 may be alternatively arranged around the four sides of the top cover shell 3 subject to an alternate form of the present invention, or arranged at opposite sides subject to another alternate form of the present invention.

Referring to FIGS. 6˜8 again, after installation of the bottom cover shell 2 and the top cover shell 3 in the circuit board 4, the through holes 222 and inspection hole 221 of the bottom cover shell 2 and the round holes 332 of the top cover shell 3 are not vertically aligned, i.e., the top cover shell 3 blocks the through holes 222 and the inspection hole 221 of the bottom cover shell 2 and the bottom cover shell 2 blocks the round holes 332 of the top cover shell 3, ensuring positive EMI protection and good grounding effect.

When wishing to examine the electronic components 41 of the circuit board 4, insert a lever or like tool into the round holes 332 of the top cover shell 3, and then stop the bottom end of the lever against the top wall of the bottom cover shell 2, and then turn the lever to lift the top cover shell 3 from the bottom cover shell 2. After removal of the top cover shell 3, the user can access to the electronic components 41 of the circuit board 4 through the inspection hole 221.

A prototype of EMI protective cover has been constructed with the features of FIGS. 1˜8. The EMI protective cover functions smoothly to provide all of the features discussed earlier.

Although a particular embodiment of the invention has been described in detail for purposes of illustration, various modifications and enhancements may be made without departing from the spirit and scope of the invention. Accordingly, the invention is not to be limited except as by the appended claims.

1. An EMI (electromagnetic interference) protective cover for installation in a circuit board to protect electronic components of said circuit board against electromagnetic interference, comprising:
a bottom cover shell for covering on a circuit board over electronic components at the circuit board, said bottom cover shell having a plurality of vertical peripheral wall around the border of a top wall thereof, and a plurality of stub pins perpendicularly outwardly extended from said vertical peripheral wall; and
a top cover shell detachably covered on said bottom cover shell, said top cover shell comprising a plurality of springy mounting lugs and smoothly arched springy retaining lugs perpendicularly downwardly extended around four sides thereof and respectively pressed on the vertical peripheral walls of said bottom cover shell, said springy mounting lugs each having a pin hole respectively forced into engagement with the stub pins of said bottom cover shell.

2. The EMI protective cover as claimed in claim 1, wherein said top cover shell comprises a plurality of round holes extended through a top wall thereof, and a stop member for pressing on the top wall of said bottom cover shell.

3. The EMI protective cover as claimed in claim 1, wherein said stop member of said top cover shell is a springy stop member obliquely downwardly projecting from the top wall of said top cover shell into an inside space surrounded by said springy mounting lugs and said springy retaining lugs and pressed on the top wall of said bottom cover shell.

4. The EMI protective cover as claimed in claim 1, wherein said bottom cover shell has a plurality of through holes and an inspection hole through the top wall in communication with an inside space surrounded by the top wall and vertical peripheral walls of said bottom cover shell.

5. The EMI protective cover as claimed in claim 1, wherein said springy mounting lugs and said springy retaining lugs are symmetrically disposed at opposite sides.

6. The EMI protective cover as claimed in claim 1, wherein said springy mounting lugs and said springy retaining lugs are alternatively arranged around the four sides
